(19) United States
(12) Patent Application Publication
(10) Pub. No.: US 2025/0029944 A1
(43) Pub. Date: Jan. 23, 2025

(54) MEMORY DEVICE AND METHOD OF MANUFACTURING MEMORY DEVICE

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 18/538,967

(22) Filed: Dec. 13, 2023

(30) Foreign Application Priority Data
Jul. 20, 2023 (KR) 10-2023-0094811

(51) Int. Cl. H01L 23/00; H01L 21/02; H10B 80/00

(52) U.S. Cl. CPC H01L 24/08; H01L 21/02362; H01L 24/03; H01L 24/05; H10B 80/00; H01L 2224/0347; H01L 2224/05147; H01L 2224/08147

(57) ABSTRACT

A memory chip includes a plurality of micro pattern lines, a capping layer covering portions of the micro pattern lines. A bonding pad penetrates the capping layer and is coupled to one of the micro pattern lines. The bonding pad includes a first pad portion coupled to the associated micro pattern line and a second pad portion coupled to the first pad portion and exposed to a top surface of the memory chip. An upper surface of the second pad portion has a convex shape.

### CROSS-REFERENCE TO RELATED APPLICATION

The present application claims priority under 35 U.S.C. § 119 (a) to Korean patent application number 10-2023-0094811 filed on Jul. 20, 2023, in the Korean Intellectual Property Office, the entire disclosure of which is incorporated by reference herein.

### BACKGROUND

### 1. Technical Field

Various embodiments of the present disclosure generally relate to an electronic device, and more particularly to a memory device and a method of manufacturing the memory device.

### 2. Related Art

A nonvolatile memory device is a memory device in which stored data is maintained even if power supply is cut off. Recently, as the integration of a two-dimensional nonvolatile memory device that forms memory cells in a single layer on a substrate is limited, a three-dimensional nonvolatile memory device that vertically stacks the memory cells on the substrate has been proposed.

A three-dimensional nonvolatile memory device includes alternately-stacked interlayer insulators and gate electrodes and channel layers which penetrate the alternately-stacked interlayer insulators and the gate electrodes. Memory cells are stacked along the channel layers. Various structures and manufacturing methods are being developed to improve the reliability of three-dimensional nonvolatile memory devices.

### SUMMARY

Various embodiments of the present disclosure are directed to a memory chip including a bonding pad coupled to micro patterns and a method of manufacturing the memory chip.

As used herein, the term, “micro pattern line” should be construed as referring to a layer of electrically-conductive material formed within a semiconductor material or formed on the surface of a semiconductive material and which carries electrical signals (voltages or current) between two or more electrical nodes. A “micro pattern line” should not be construed as necessarily straight or having a particular cross-sectional shape. A “micro pattern line” is also not necessarily formed in or on a particular geometric plane; a micro pattern line may thus have both vertical and horizontal portions.

An embodiment of the present disclosure may provide for a three-dimensional semiconductor memory device that may include a plurality of micro pattern lines, a capping layer covering upper portions of the plurality of micro pattern lines, and at least one bonding pad penetrating the capping layer to be coupled to any one of the micro pattern lines. The bonding pad includes a first portion, which is referred to as a “first pad portion” that is electrically and mechanically coupled to the associated micro pattern line. The bonding pad also includes a second portion, referred to herein as a “second pad portion” that is electrically coupled to the first pad portion and which is exposed to the exterior or outside of the device. An upper surface of the second pad portion has a convex shape.

An embodiment of the present disclosure may provide for a semiconductor memory cell array comprising: a plurality of bit lines located on the memory cell array; first bonding pads coupled to the plurality of bit lines, respectively; a metal line, and second bonding pads coupled to the metal line. The first bonding pads and the second bonding pads are bonded, and each of the first bonding pads has a pin structure.

A second embodiment of the present disclosure may provide a method of manufacturing a semiconductor memory cell array comprising a plurality of bit lines on a substrate, the method comprising: forming a capping layer on upper portions of the plurality of bit lines and then forming a plurality of holes through which the plurality of bit lines are exposed; forming a barrier metal layer and a metal seed layer along an upper surface of the capping layer and sidewalls and bottom surfaces of the plurality of holes; forming a pad mask pattern including openings through which pad areas overlapping the holes are exposed on the metal seed layer; and forming bonding pad patterns filling the openings.

### BRIEF DESCRIPTION OF THE DRAWINGS

FIG. 1 is a block diagram illustrating a memory chip according to an embodiment of the present disclosure.

FIG. 2 is a perspective view illustrating a portion of the memory chip according to an embodiment of the present disclosure.

FIGS. 3A and 3B are plan views schematically illustrating examples of a memory chip of FIG. 2.

FIG. 4 is a sectional view illustrating a portion of the memory chip according to an embodiment of the present disclosure.

FIGS. 5A and 5B are perspective views illustrating examples of a first bonding pad of FIG. 4.

FIGS. 6A to 6F are horizontal cross-sectional views illustrating a method of manufacturing a memory chip according to an embodiment of the present disclosure.

FIG. 7 is a block diagram illustrating a memory system including a memory chip according to an embodiment of the present disclosure.

### DETAILED DESCRIPTION

Specific structural or functional descriptions in the embodiments of the present disclosure introduced in this specification or application are only for description of the embodiments of the present disclosure. The descriptions should not be construed as being limited to the embodiments described in the specification or application.

Hereinafter, the embodiments of the present disclosure will be described with reference to the accompanying drawings to the extent that a person skilled in the art to which the present disclosure pertains can easily practice the technical spirit of the present disclosure.

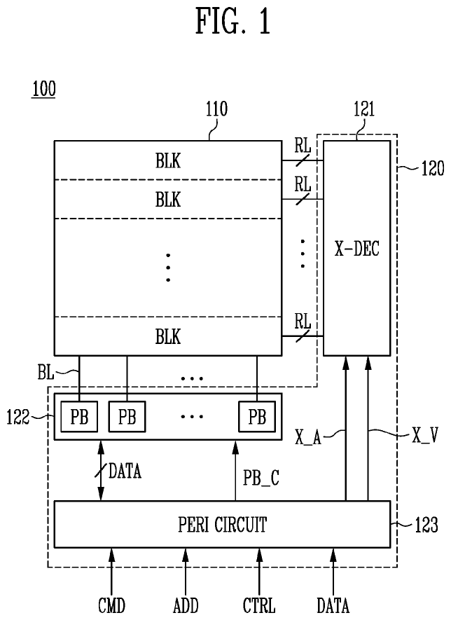

FIG. 1 is a block diagram illustrating a semiconductor memory device 100 according to an embodiment of the present disclosure. For brevity purposes a semiconductor memory device 100 is referred to hereafter as a memory device 100. The memory device 100 may include a memory cell array 110 and a logic circuit 120. The logic circuit 120 may include a row decoder (X-DEC) 121, a page buffer circuit 122, and a peripheral circuit (PERI circuit) 123.

The memory cell array 110 may include a plurality of memory blocks, each memory block being denominated with the identifier: “BLK.” Not shown in the drawing is that each memory block BLK may include a plurality of cell strings. Each cell string may include at least one drain select transistor, a plurality of memory cells, and at least one source select transistor, all of which are coupled in series.

The memory cells of the memory cell array 110 may be volatile memory cells or nonvolatile memory cells. Hereinafter, the memory device 100 will be described as a vertical NAND flash device, but it should be understood that the technical idea of the present disclosure is not limited thereto.

The memory cell array 110 may be coupled to the row decoder 121 through a plurality of row lines RL. The row lines RL may include at least one drain select line, not shown in FIG. 1, a plurality of word lines not shown in FIG. 1 and at least one source select line not shown in FIG. 1. The memory cell array 110 may be coupled to the page buffer circuit 122 through bit lines BL.

The row decoder 121 may select any one of the memory blocks BLK in the memory cell array 110 in response to a row address X_A provided to the row decoder 121 by the peripheral circuit 123. The row decoder 121 may transmit an operating voltage X_V provided from the peripheral circuit 123 to the row lines RL coupled to a memory block selected from among the memory blocks BLK included in the memory cell array 110.

The page buffer circuit 122 may include a plurality of page buffers PB coupled to the bit lines BL, respectively. The page buffer circuit 122 may receive a page buffer control signal PB_C from the peripheral circuit 123, and may transmit and receive a data signal DATA to and from the peripheral circuit 123. The page buffer circuit 122 may control the bit lines BL arranged on the memory cell array 110 in response to the page buffer control signal PB_C. For example, the page buffer circuit 122 may detect data stored in the memory cell of the memory cell array 110 by sensing the signal of a bit line BL of the memory cell array 110 in response to the page buffer control signal PB_C, and may transmit the data signal DATA to the peripheral circuit 123 according to the detected data. The page buffer circuit 122 may apply a signal to a bit line BL on the basis of the data signal DATA received from the peripheral circuit 123 in response to the page buffer control signal PB_C, so data may be written to the memory cell of the memory cell array 110. The page buffer circuit 122 may write or read data to or from the memory cell coupled to an activated word line.

The peripheral circuit 123 may receive a command signal CMD, an address signal ADD, and a control signal CTRL from the outside of the semiconductor device 100, and may transmit and receive the data DATA to and from a device outside the semiconductor device 100, for instance, a memory controller. The peripheral circuit 123 may output signals for writing or read data to or from the memory cell array 110 on the basis of the command signal CMD, the address signal ADD, and the control signal CTRL, for instance, the row address X_A or the page buffer control signal PB_C. The peripheral circuit 123 may generate various voltages required by the semiconductor device 100, including the operating voltage X_V.

As used herein, the term “memory chip” should be construed as a referring to a semiconductor substrate having substantially planar top and bottom surfaces, between which is one or more semiconductor materials in which one or more electronic devices, transistors and resistors, et al., are formed using well-known semiconductor fabrication techniques.

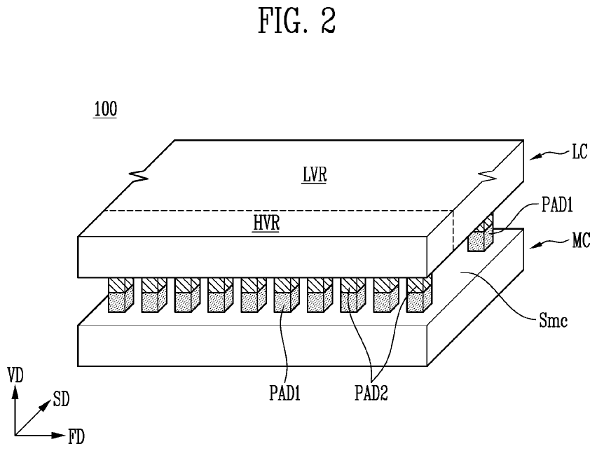

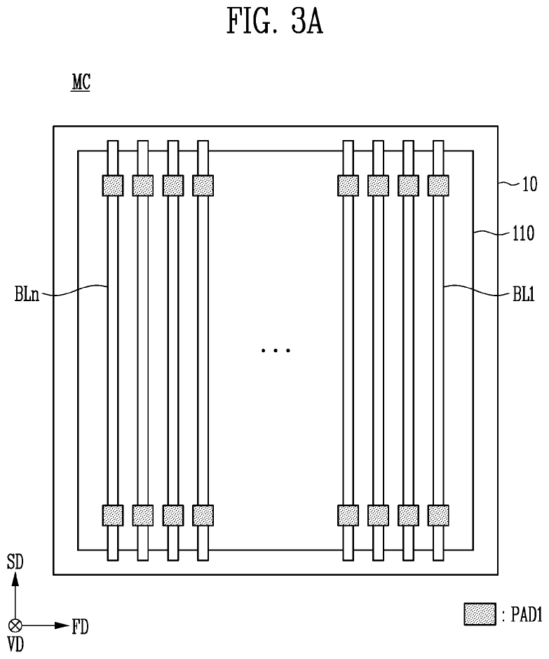

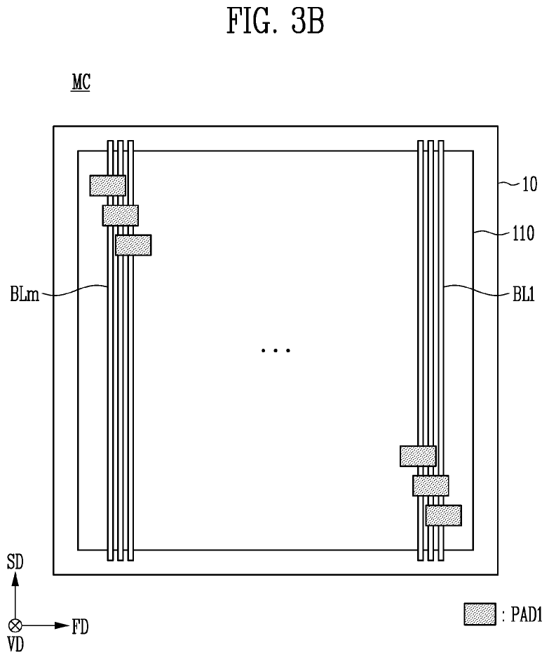

FIG. 2 is a perspective view illustrating a portion of the physical structure of the memory device 100 according to an embodiment of the present disclosure. FIGS. 3A and 3B are plan views schematically illustrating a physical layout of a memory chip MC, in which the memory device of FIG. 1 is embodied.

Referring to FIG. 2, the memory device 100 according to an embodiment of the present disclosure may include a memory chip MC and a logic chip LC bonded on the memory chip MC. The memory device 100 may have a Peripheral Over Cell (POC) structure.

Referring to FIG. 3A, the memory chip MC may include the memory cell array 110 located on a first substrate 10 and a plurality of bit lines BL1 to BLn located on the memory cell array 110. Each bit line BL1 to BLn may extend in a second direction SD, as shown in the figure. Several of the electrically and physically parallel bit lines BL1-BLn the lengths of which extend in the second direction SD, are adjacent to but laterally separated from each other by distance that extends in the first direction FD. As shown in the figure, FD and SD orthogonal to each other. The bit lines, BL1-BLn, the first direction FD and the second direction SD may all lie in the same geometric plane, which is parallel to and vertically separated from a geometric plane of the upper surface of the substantially planar first substrate 10. The first direction FD may correspond to the extending direction of word lines, while the second direction SD may correspond to the extending direction of bit lines. A vertical direction VD, which extends into and out of the plane of FIG. 3A as shown, may protrude vertically from the upper surface of the first substrate 10, and may perpendicularly intersect the first direction FD and the second direction SD.

A plurality of first bonding pads PAD1 may be provided on a surface Smc of the memory chip MC facing the logic chip LC (see FIG. 2). Each of the plurality of bit lines BL1 to BLn may be coupled to at least one first bonding pad PAD1. Although it is shown and described that one bit line BL is coupled to one first bonding pad PAD1 in an embodiment of the present disclosure, a plurality of first bonding pads PAD1 may be commonly coupled to one bit line BL. A first bonding pad PAD1 may thus overlap multiple ones of the plurality of bit lines BL1 to BLn. A lower portion of each of the first bonding pads PAD1 may be electrically and physically connected to a corresponding one of the lines BL of the plurality of bit lines BL1 to BLn.

As the integration degree of the semiconductor device increases, the number of bit lines BL arranged in the same area of the memory cell MC may increase. This may require one or both of the width of a bit line and the separation distance between adjacent bit lines to decrease.

Referring to FIG. 3B, the memory chip MC may include a memory cell array 110 located on the first substrate 10 and a plurality of bit lines BL1 to BLm (where m is a positive integer greater than n) also located on the memory cell array 110. Each bit line of the plurality of bit lines BL1 to BLm may have the same constant width. Each bit line may be arranged to be spaced apart from adjacent bit lines by the same preset distance.

As shown in FIG. 3B, the length of each bit line of the plurality of bit lines BL1 to BLm may extend in the second direction SD. The bit lines BL1 to BLm may be laterally separated from each other by a separation distance that extends in the first direction FD. The bit lines of the plurality of bit lines BL1 to BLm may be arranged to be parallel to each other. As the number of the plurality of bit lines BL1 to BLm increases, the number of the first bonding pads PAD1 corresponding to the plurality of bit lines BL1 to BLm also increases, and the first bonding pads PAD1 corresponding to adjacent bit lines may be arranged diagonally between the first direction FD and the second direction SD to maintain a physical separation from each other. Furthermore, one first bonding pad PAD1 may overlap one or more bit lines. A lower portion of each of the first bonding pads PAD1 may be electrically and physically connected to a corresponding bit line among the plurality of bit lines BL1 to BLn.

Although it is shown and described that the first bonding pads PAD1 are diagonally arranged in an embodiment of the present disclosure, bonding pads PAD1 adjacent to each other may be arranged in a zigzag direction.

Referring again to FIG. 2, the logic chip LC may be bonded on the memory chip MC so that the second bonding pads PAD2 are coupled to the first bonding pads PAD1.

The logic chip LC may include the logic circuit 120 of FIG. 1. That is, the logic chip LC may include a high-voltage transistor region HVR and a low-voltage transistor region LVR. The high-voltage transistor region HVR is a region in which high-voltage transistors are arranged, and the low-voltage transistor region LVR is a region in which low-voltage transistors are arranged.

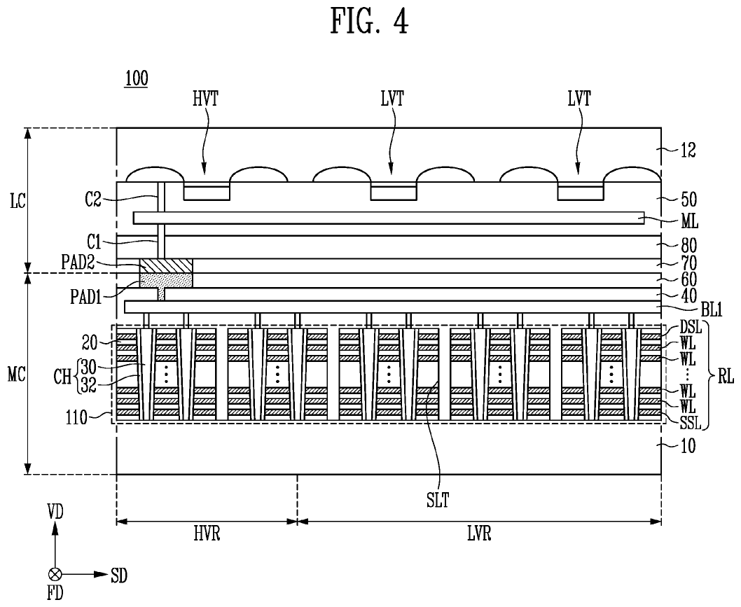

FIG. 4 is a sectional view illustrating a portion of the semiconductor device according to an embodiment of the present disclosure.

Referring to FIG. 4, the memory chip MC may include the first substrate 10. The memory cell array 110 may be located on the first substrate 10.

The first substrate 10 may be formed as either a single crystal silicon layer, SOI (Silicon On Insulator), a silicon layer formed on a silicon germanium (SiGe) layer, a single crystal silicon layer formed on an insulator, or a polysilicon layer formed on the insulator. According to an embodiment, the memory chip MC may include a line structure coupled to the memory cell array 110 by performing an additional line forming process after removing the first substrate 10.

The memory cell array 110 may include a plurality of row lines RL and a plurality of interlayer insulators 20 that are alternately stacked on the first substrate 10, and a plurality of channel structures CH penetrating the row lines RL and the interlayer insulators 20 in a vertical direction VD. At least one layer from the bottom among the row lines RL may form a source select line SSL. At least one layer from the top may form a drain select line DSL. Row lines RL between the source select line SSL and the drain select line DSL may form word lines WL.

Each of the plurality of channel structures CH may include a channel layer 30 and a gate insulating layer 32. The channel layer 30 may be polysilicon or single crystal silicon, and may include P-type impurities such as boron (B). The gate insulating layer 32 shape may resemble a hollow tube of cylinder to enclose the outer wall of the channel layer 30. The gate insulating layer 32 may include a tunnel insulator, a charge storage layer, and a blocking layer that are sequentially stacked from the outer wall of the channel layer 30. In some embodiments, the gate insulating layer 32 may have an Oxide-Nitride-Oxide (ONO) stacked structure in which an oxide layer, a nitride layer, and an oxide layer are sequentially stacked. Source select transistors may be formed in portions where the source select line SSL encloses a plurality of channel structures CH. Memory cells may be formed in portions where the word lines WL enclose the plurality of channel structures CH. Drain select transistors may be formed in portions where the drain select line DSL encloses the plurality of channel structures CH.

A bit line (e.g., BL1) may be provided on a channel structure CH. The bit line BL1 may extend in the second direction SD. Although only one bit line BL1 is shown in FIG. 4, it should be understood that a plurality of bit lines BL1 to BLm (see FIG. 3B) are repeatedly arranged in the first direction FD, which as shown in FIG. 4 extends into and out of the geometric plane on which FIG. 4 is drawn.

Bit line contacts BLC may be provided under the bit line BL1 to couple a bit line BL1 and a channel structure CH. A plurality of channel structures CH arranged in a row that extends along the second direction SD and may be coupled in common to one bit line BL1.

Slits SLT may be provided in the row lines RL and the interlayer insulators 20 that are alternately stacked, so that the slits SLT may separate the row lines RL, the interlayer insulators 20, and the channel structures CH into memory block units or memory finger units, which are blocks smaller than a memory block.

A capping layer 40 may be provided on the first substrate 10 to cover the row lines RL and the interlayer insulators 20 that are alternately stacked, the channel structures CH, and the bit line BL1. A first buffer layer 60 may be formed on the capping layer 40, and the upper surface of the first buffer layer 60 may form a side of the memory chip MC facing the logic chip LC. A first bonding pad PAD1 may be located on a side of the memory chip MC. The first bonding pad PAD1 may be exposed to a side of the memory chip MC. The first bonding pad PAD1 may be located in the first buffer layer 60, and may extend into the capping layer 40 to be directly coupled to the bit line BL1. Although FIG. 4 shows only one first bonding pad PAD1, it should be understood that the plurality of first bonding pads PAD1 are repeatedly arranged in the first direction FD to be coupled to the corresponding bit lines, respectively. The first bonding pad PAD1 may have a pin structure. The first bonding pad PAD1 may have a T shape.

The logic chip LC may include a second substrate 12 and a plurality of transistors HVT and LVN located on the second substrate 12. The second substrate 12 may be formed of a single crystal silicon layer, SOI, a silicon layer formed on a silicon germanium layer, a single crystal silicon layer formed on the insulator, or a polysilicon layer formed on the insulator. The second substrate 12 may be formed of the same material as the first substrate 10.

The transistors HVT and LVN may include a high-voltage transistor HVT located on the high-voltage transistor region HVR of the second substrate 12 and low-voltage transistors LVT located on the low-voltage transistor region LVR of the second substrate 12. Although FIG. 4 shows one high-voltage transistor HVT and two low-voltage transistors LVT, it should be understood that a plurality of high-voltage transistors HVT and a plurality of low-voltage transistors LVT may be provided on the second substrate 12.

A metal line ML may be located on the second substrate 12 and may be coupled to the high-voltage transistor HVT through a second contact C2. Further, the metal line ML may be coupled through a first contact C1 to the second bonding pad PAD2. The first contact C1 may penetrate an insulator 80 to be coupled to the second bonding pad PAD2.

An insulator 50 may be provided on the second substrate 12 to cover the transistors HVN and LVN and the metal line ML. The insulator 50 may be silicon oxide, e.g., HDP oxide or TEOS oxide. The insulator 80 and the second buffer layer 70 may be formed over the insulator 50. The upper surface of the second buffer layer 70 may form a side of the logic chip LC facing the memory chip MC. The second bonding pad PAD2 may be provided on a side of the logic chip LC. In other words, the second bonding pad PAD2 may be located in the second buffer layer 70, and the upper surface thereof may be exposed to a side of the logic chip LC.

The first bonding pad PAD1 may correspond to the second bonding pad PAD2. The first bonding pad PAD1 and the second bonding pad PAD2 may be arranged to face each other. In order to couple the corresponding first bonding pad PAD1 and second bonding pad PAD2 to each other, the logic chip LC may be bonded on the memory chip MC. The first bonding pad PAD1, the second bonding pad PAD2, and the first contact C1 may form an electrical path to couple the bit line BL1 of the memory chip MC and the metal line ML of the logic chip LC.

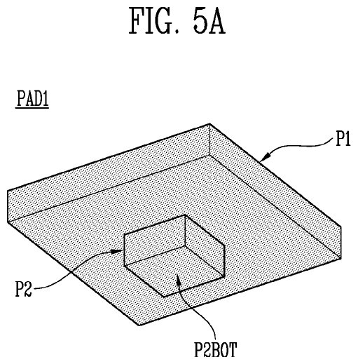

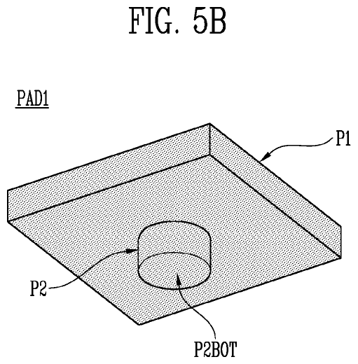

FIGS. 5A and 5B are perspective views illustrating examples of the first bonding pad of FIG. 4.

Referring to FIGS. 5A and 5B, the first bonding pad PAD1 may include a first pad portion P1 and a second pad portion P2. The first pad portion P1 is a portion exposed through a top surface TS of the memory chip MC of FIG. 4. The first pad portion P1 may have a shape that is substantially rectilinear, i.e., characterized by straight lines such that its shape is reminiscent of a rectangular parallelepiped or plate. The second pad portion P2 may contact the bottom surface of the first pad portion P1, and extend toward and make electrical and mechanical contact with the bit line BL1 of FIG. 4. The second pad portion P2 may also have the shape of a rectangular parallelepiped or square pillar as shown in FIG. 5A. In an alternate embodiment, the second pad portion P2 may be cylindrical as shown in FIG. 5B. The bottom surface P2BOT of the second pad portion P2 may directly contact the bit line BL1 of FIG. 4.

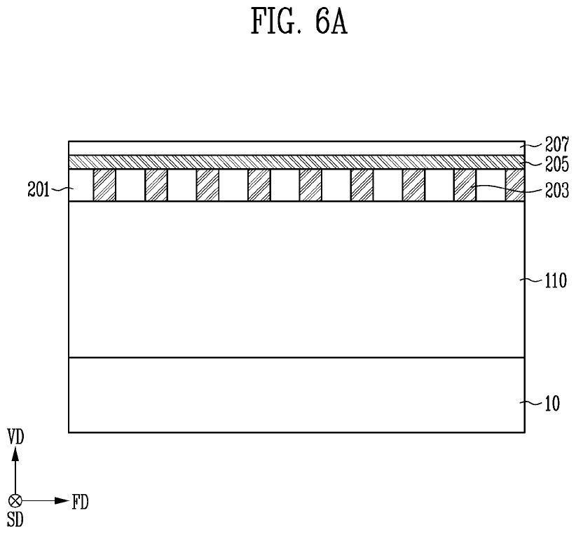

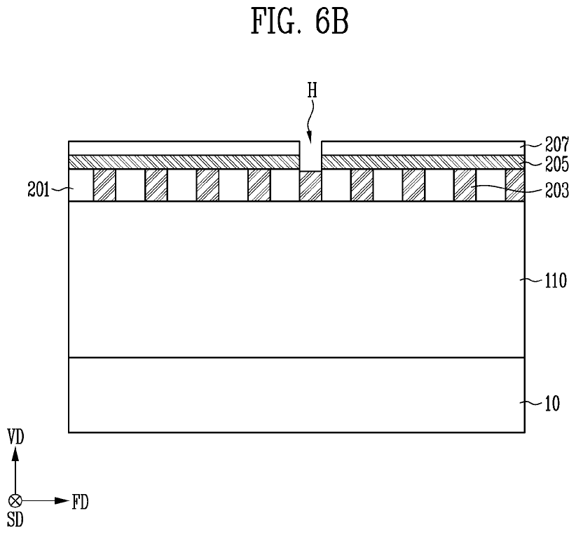

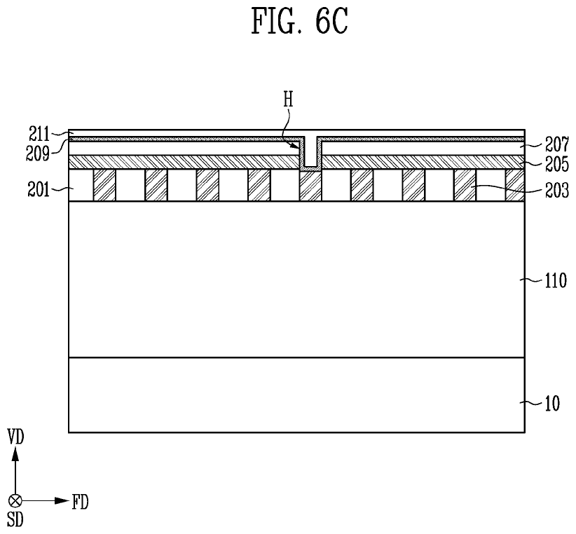

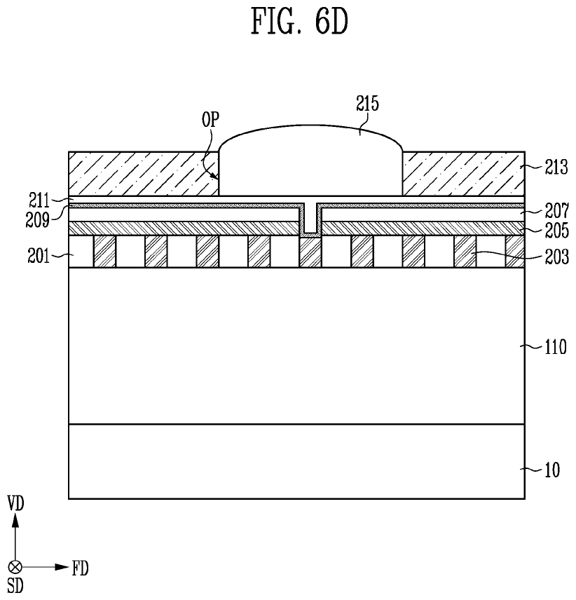

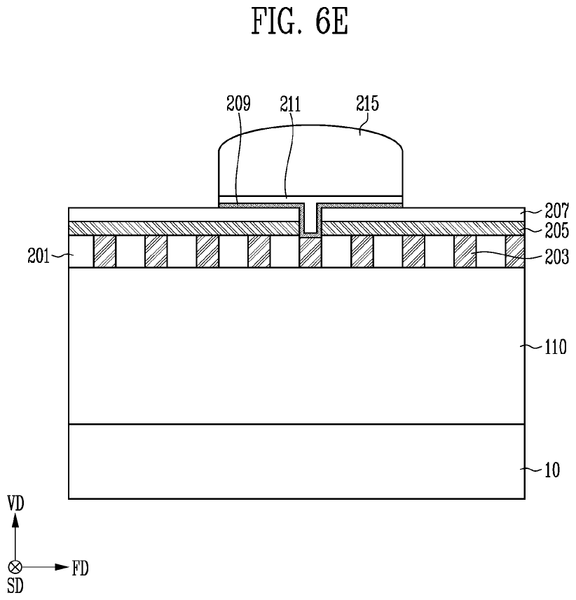

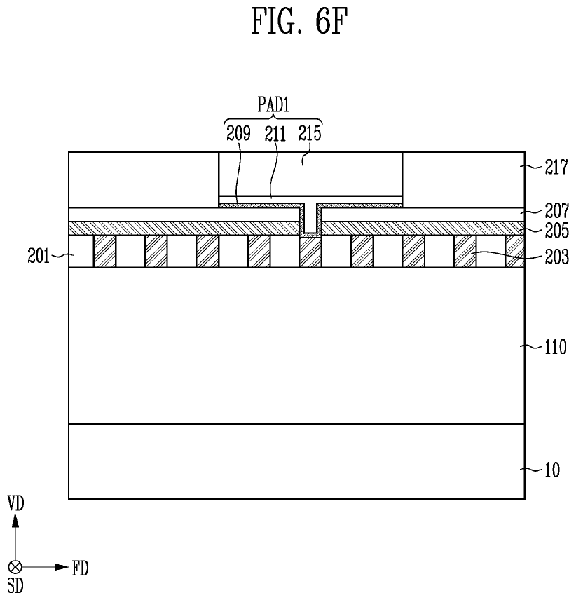

FIGS. 6A to 6F are vertical cross-sectional views illustrating steps of a method of manufacturing a semiconductor memory device according to an embodiment of the present disclosure described above and shown in FIGS. 1-5B.

Referring to FIG. 6A, the memory cell array 110 is formed on a first substrate 10. The memory cell array 110 may be the memory cell array 110 of FIG. 4 and may include a structure in which a plurality of interlayer insulators and a plurality of conductive layers for word lines are alternately stacked. The structure may also include a plurality of channel structures penetrating the stacked structure in a vertical direction, VD as shown in FIG. 6A.

Next, a first insulator 201 that may include an oxide layer is formed on the memory cell array 110, Micro pattern lines 203 are formed to penetrate at least part of the first insulator 201. The micro pattern lines 203 are coupled to the memory cell array 110. The plurality of micro pattern lines 203 may be line-like structures, i.e., thin, narrow and elongated layers, formed of a conductive material. The plurality of micro pattern lines 203 may be the plurality of bit lines BL1 to BLn and BL1 to BLm shown in FIGS. 3A and 3B. The plurality of micro pattern lines 203 may extend in the second direction SD, and be arranged in the first direction FD. The plurality of micro pattern lines 203 each may have a constant width, and be arranged to be spaced apart from each other at regular intervals.

Next, the first insulator 201 is overlaid by a first capping layer 205, which is formed over the plurality of micro pattern lines 203. A second capping layer 207 is then overlaid the first capping layer 205. The capping layers are preferably non-conductive. The first capping layer 205 may contain a silicon nitride layer (SIN). The second capping layer 207 may contain a silicon oxide layer (SiO₂).

Referring to FIG. 6B, after forming a photoresist pattern (not shown) on the second capping layer 207, an etching process using the photoresist pattern (not shown) is performed to form a hole H through which each of the plurality of micro pattern lines 203 is exposed. Although one hole H is shown in the embodiment of the present disclosure, a plurality of holes may be formed to correspond to the plurality of micro pattern lines 203, respectively. The plurality of holes may be formed so as not to overlap each other. For example, the plurality of holes may be arranged diagonally between the first direction FD and the second direction SD.

During the process of forming the holes H, a primary etching process may be performed to etch the second capping layer 207 and thereby expose the first capping layer 205. Thereafter, a secondary etching process may be performed to form the hole H and thereby expose the plurality of micro pattern lines 203.

Subsequently, the photoresist pattern is removed.

Referring to FIG. 6C, a barrier metal layer 209 may be formed on the upper surface of the second capping layer 207, the sidewall and the bottom surface of the hole H. Thereafter, a metal seed layer 211 is formed on the barrier metal layer 209. The metal seed layer 211 may completely fill the inside of the hole H and may contain copper (Cu).

Referring to FIG. 6D, a pad mask pattern 213 is formed on the metal seed layer 211. The pad mask pattern 213 may include an opening OP through which a pad area overlapping the hole H is exposed. The pad mask pattern 213 may be formed as a photoresist pattern.

Subsequently, a bonding pad material 215 is formed in the opening OP of the pad mask pattern 213. The bonding pad material 215 may contain copper (Cu). For example, the bonding pad material 215 may be formed or deposited by selectively growing exposed portions of the metal seed layer 211 inside the hole H. For example, the bonding pad material 215 may be formed through an electroplating method. The upper surface of the bonding pad material 215 may be convex.

According to an embodiment, the bonding pad material 215 may be formed by gap-filling a metal material in the opening OP.

Referring to FIG. 6E, the pad mask pattern 213 (see FIG. 6D) is removed to expose the metal seed layer 211. Subsequently, the exposed metal seed layer 211 and the barrier metal layer 209 are sequentially etched away, the etching process preferably being a wet etching process. Thus, the metal seed layer 211 and the barrier metal layer 209 may remain only under the bonding pad material 215.

Referring to FIG. 6F, a buffer layer 217 may be formed on an entire structure including the bonding pad material 215, and a planarization process (CMP; Chemical Mechanical Polishing) may be performed to expose the upper surface of the bonding pad material 215. The buffer layer 217 may include silicon carbon nitride (SiCN).

Since the barrier metal layer 209 is not exposed during the planarization process, it is possible to prevent steps from occurring between the bonding pad material 215 and materials of the barrier metal layer 209 and the buffer layer 217. Further, the plurality of micro pattern lines 203 may be directly coupled to the first bonding pad PAD1, thus simplifying a process.

The first bonding pad PAD1 may be formed to include the barrier metal layer 209, the metal seed layer 211, and the bonding pad material 215. The first bonding pad PAD1 may be the first bonding pad PAD1 of FIG. 4. The first bonding pad PAD1 may have a damascene structure that fills the hole H (see FIG. 6C) and the opening OP (see FIG. 6D). The first bonding pad PAD1 may have a pin structure. The first bonding pad PAD1 may have a T shape.

According to the above-described embodiment, the first bonding pad PAD1 may include a first pad portion (corresponding to P1 of FIGS. 5A and 5B) filling the opening OP (FIG. 6D) and a second pad portion (corresponding to P2 of FIGS. 5A and 5B) filling the hole H (FIG. 6C). For instance, the second pad portion P2 of the first bonding pad PAD1 overlaps one corresponding micro pattern line 203 to be mechanically and electrically coupled thereto but does not overlap micro pattern lines adjacent to the corresponding micro pattern line 203. The first pad portion P1 of the first bonding pad PAD1, however may overlap the corresponding micro pattern line 203 and the adjacent micro pattern lines.

Further, the first bonding pad PAD1 may include the barrier metal layer 209, but the barrier metal layer 209 may be formed only on the bottom surface of the first bonding pad PAD1. The side surface of the first bonding pad PAD1 may have a structure in which the metal seed layer 211 and the bonding pad material 215 contact the buffer layer 217.

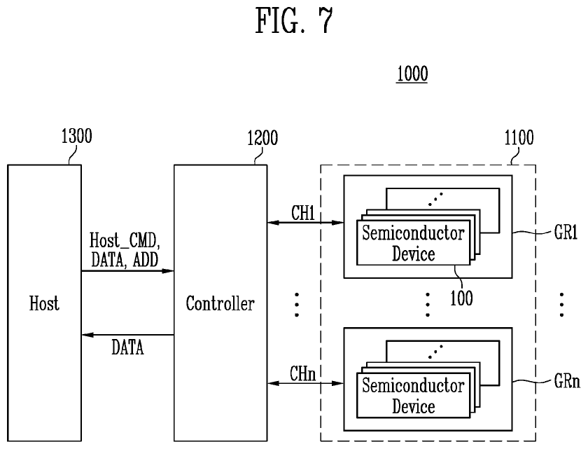

FIG. 7 is a block diagram illustrating a memory system including a semiconductor device in accordance with an embodiment of the present disclosure.

Referring to FIG. 7, a memory system 1000 may include a memory device 1100, a controller 1200, and a host 1300. The memory device 1100 may include a plurality of semiconductor devices 100. The plurality of semiconductor devices 100 may be divided into a plurality of groups. Although in the present embodiment the host 1300 has been illustrated and described as being included in the memory system 1000, the memory system 1000 may include only the controller 1200 and the memory device 1100, and the host 1300 may be located outside the memory system 1000.

In FIG. 7, it is illustrated that a plurality of groups GR1 to GRn of the memory device 1100 communicate with the controller 1200 through first to n-th channels CH1 to CHn, respectively. Each memory device 100 may be the semiconductor device described with reference to FIGS. 1, 2, and 5.

Each of the groups GR1 to GRn may communicate with the controller 1200 through one common channel. The controller 1200 may control the plurality of semiconductor devices 100 of the memory device 1100 through the plurality of channels CH1 to CHn.

The controller 1200 is coupled between the host 1300 and the memory device 1100. The controller 1200 may access the memory device 1100 in response to a request from the host 1300. For example, the controller 1200 may control a read operation, a program operation, an erase operation, and a background operation of the memory device 1100 in response to a host command Host_CMD received from the host 1300. The host 1300 may transmit an address ADD and data DATA to be programmed along with the host command Host_CMD during the program operation, and may transmit the address ADD along with the host command Host_CMD during the read operation. During the program operation, the controller 1200 transmits a command corresponding to the program operation and data DATA to be programmed to the memory device 1100. During the read operation, the controller 1200 transmits a command corresponding to the read operation to the memory device 1100, receives the read data DATA from the memory device 1100, and transmits the received data DATA to the host 1300. The controller 1200 may provide an interface between the memory device 1100 and the host 1300.

The controller 1200 may run firmware for controlling the memory device 1100. The host 1300 may include a portable electronic device such as a computer, a personal digital assistant (PDA), a portable multimedia player (PMP), an MP3 player, a camera, a camcorder, or a mobile phone. The host 1300 may use the host command Host_CMD to make a request for the program operation, the read operation, the erase operation, etc. of the memory system 1000. To perform the program operation of the memory device 1100, the host 1300 may transmit the host command Host_CMD corresponding to the program operation, the data DATA, and the address ADD to the controller 1200. To perform the read operation, the host may transmit the host command Host_CMD corresponding to the read operation, and the address ADD to the controller 1200. Here, the address ADD may be a logical address of data.

The controller 1200 and the memory device 1100 may be integrated into a single device. As an embodiment, the controller 1200 and the memory device 1100 may be integrated into the single device to form a memory card. For example, the controller 1200 and the memory device 1100 may be integrated into the single device to form the memory card such as a PC card (PCMCIA, personal computer memory card international association), a compact flash card (CF), a smart media card (SM, SMC), a memory stick, a multimedia card (MMC, RS-MMC, MMCmicro), a SD card (SD, miniSD, microSD, SDHC), or a universal flash storage (UFS).

In an embodiment, the memory system 1000 may be provided as one of various components of an electronic device such as a computer, a ultra mobile PC (UMPC), a workstation, a net-book, a personal digital assistant (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, one of various components for forming a computing system, or the like.

In an embodiment, the memory device 1100 or the memory system 1000 may be mounted in various types of packages. For example, the memory device 1100 or the memory system 1000 may be packaged in a Package on Package (POP), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flat pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), Wafer-Level Processed Stack Package (WSP), or the like.

The foregoing description is for illustration purposes. The true scope of the invention is defined by the claims.

What is claimed is:

1. A memory chip comprising:
a plurality of micro pattern lines;
a capping layer covering portions of the micro pattern lines; and
a bonding pad penetrating the capping layer, said bonding pad being electrically coupled to a predetermined micro pattern line;
wherein the bonding pad comprises:
a first pad portion electrically coupled to the predetermined micro pattern line; and
a second pad portion coupled to the first pad portion and exposed at a top surface of the memory chip; and
wherein an upper surface of the second pad portion has a convex shape.

2. The memory chip according to claim 1, wherein the bonding pad comprises:
a barrier metal layer located on a sidewall and a bottom surface of the first pad portion and a bottom surface of the second pad portion; and
a bonding pad material disposed on the barrier metal layer.

3. The memory chip according to claim 2, wherein the bonding pad material comprises copper.

4. The memory chip according to claim 2, wherein the barrier metal layer is located only on the bottom surface of the bonding pad.

5. The memory chip according to claim 2, wherein the first pad portion penetrates the capping layer.

6. The memory chip according to claim 5, wherein the capping layer comprises:
a first capping layer disposed on the upper portions of the plurality of micro pattern lines, and including a silicon nitride layer; and
a second capping layer disposed over the first capping layer, and including a silicon oxide layer.

7. The memory chip according to claim 5, further comprising:
a buffer layer disposed over the capping layer,
wherein a side of the second pad portion contacts the buffer layer.

8. The memory chip according to claim 7, wherein the buffer layer contacts the bonding pad material.

9. The memory chip according to claim 1, wherein the second pad portion overlaps micro pattern lines located adjacent to the predetermined micro pattern line.

10. The memory chip according to claim 1, wherein the bonding pad has a damascene structure.

11. The memory chip according to claim 1, wherein the bonding pad has a pin structure.

12. A memory device comprising:
a memory cell array;
a plurality of bit lines located on the memory cell array;
first bonding pads coupled to the plurality of bit lines, respectively;
a metal line; and
second bonding pads coupled to the metal line,
wherein the first bonding pads and the second bonding pads are bonded, and
wherein each of the first bonding pads has a pin structure.

13. The memory device according to claim 12, wherein each of the first bonding pads comprises:
a first pad portion directly coupled to any one of the plurality of bit lines; and
a second pad portion coupled to the first pad portion.

14. The memory device according to claim 13, wherein each of the bonding pads comprises:
a barrier metal layer located on a sidewall and a bottom surface of the first pad portion and a bottom surface of the second pad portion; and
a bonding pad material disposed on the barrier metal layer.

15. The memory device according to claim 14, wherein the barrier metal layer is located only on a bottom surface of each of the first bonding pads.

16. The memory device according to claim 15, further comprising:
a capping layer and a buffer layer sequentially disposed on upper portions of the plurality of bit lines,
wherein the first pad portion penetrates the capping layer, and the second pad portion penetrates the buffer layer.

17. The memory device according to claim 16, wherein the bonding pad material contacts the buffer layer.

18. A method of manufacturing a memory device, the method comprising:
forming a memory cell array and a plurality of conductive patterns on a substrate;
forming a capping layer on upper portions of the plurality of conductive patterns, and then forming a plurality of holes through which the plurality of conductive patterns are exposed;
forming a barrier metal layer and a metal seed layer along an upper surface of the capping layer and sidewalls and bottom surfaces of the plurality of holes;
forming a pad mask pattern including openings through which pad areas overlapping the holes are exposed on the metal seed layer; and
forming bonding pad patterns filling the openings.

19. The method according to claim 18, further comprising:
forming the bonding pad patterns, removing the pad mask pattern, and sequentially etching the exposed metal seed layer and barrier metal layer; and
forming a buffer layer to cover the bonding pad patterns, and then performing a planarization process to expose upper portions of the bonding pad patterns.

20. The method according to claim 18, wherein the openings correspond to any one of the plurality of bit lines, and overlap bit lines adjacent to the predetermine bit line.

21. The method according to claim 18, wherein the metal seed layer and the bonding pad patterns comprise copper.
